(19) United States
(12) Patent Application Publication
(10) Pub. No.: US 2022/0230853 A1
(43) Pub. Date: Jul. 21, 2022

(54) DETECTION METHOD AND DETECTION APPARATUS FOR GAS DELIVERY DEVICE, AND GAS DELIVERY DEVICE

(71) Applicant: CHANGXIN MEMORY TECHNOLOGIES, INC., Hefei City (CN)

(72) Inventor: Yao Gu, Hefei City (CN)

(21) Appl. No.: 17/651,441

(22) Filed: Feb. 17, 2022

Related U.S. Application Data
(63) Continuation of application No. PCT/CN2021/111861, filed on Aug. 10, 2021.

(30) Foreign Application Priority Data
Jan. 15, 2021 (CN) 202110055353.1

(51) Int. Cl. H01J 37/32; H01L 21/67

(52) U.S. Cl. CPC H01J 37/32449; H01L 21/67253; H01L 21/67017

(57) ABSTRACT

A detection method and detection apparatus for a gas delivery device, and a gas delivery device are provided. The detection method includes: controlling a gas inlet of a machine flow control apparatus to be connected to a first gas inlet pipeline, and controlling a gas inlet valve of the gas inlet to be opened and a gas delivery valve of the machine flow control apparatus to be closed; controlling a pump valve of the machine flow control apparatus to be opened, and controlling the pump valve to be closed after a flow rate of first gas passing through a mass flow controller (MFC) in the machine flow control apparatus reaches a preset target value; obtaining a first minimum flow rate value of the first gas passing through the MFC within a first preset duration; and determining the detection result.

### CROSS-REFERENCE TO RELATED APPLICATIONS

This is a continuation of International Patent Application No. PCT/CN2021/111861, filed on Aug. 10, 2021, which claims the priority to Chinese Patent Application No. 202110055353.1, titled “DETECTION METHOD AND DETECTION APPARATUS FOR GAS DELIVERY DEVICE, AND GAS DELIVERY DEVICE” and filed on Jan. 15, 2021. The entire contents of International Patent Application No. PCT/CN2021/111861 and Chinese Patent Application No. 202110055353.1 are incorporated herein by reference.

### TECHNICAL FIELD

The present disclosure relates to the field of semiconductor manufacturing technologies, and in particular, to a detection method and detection apparatus for a gas delivery device, and a gas delivery device.

### BACKGROUND

A thin film deposition technology needs to be frequently used for fabricating semiconductor memory devices. The thin film deposition technology usually includes physical vapor deposition (PVD) and chemical vapor deposition (CVD). In a CVD process, a special gas cylinder required for reaction in a fabrication process is provided by a factory, and gas in the gas cylinder is allowed to flow into a mass flow controller (MFC) through a gas cabinet and a pipeline, and then enters a reaction chamber through a distribution plate (showerhead) to participate in reaction for film deposition.

The MFC is an important part of a gas delivery device in the thin film deposition technology. The MFC not only can accurately measure a flow rate of gas, but also can control the flow rate of the gas according to user settings. During process production, a gas inlet valve is usually opened to allow reaction gas to enter the MFC, and a gas outlet valve is opened to allow the reaction gas to flow to the reaction chamber from the MFC. In this process, due to gas inlet pipeline blockage, valve leakage, abnormal installation of the MFC, and the like, the amount of gas introduced into the reaction chamber will not satisfy an expected quantity, resulting in an abnormal film deposition thickness and even a product scrap. The amount of the reaction gas introduced into the reaction chamber will be less than the expected amount due to the gas inlet pipeline blockage or valve leakage, and an incorrect installation direction of the MFC will lead to an inaccurate flow detection mechanism of the MFC. Consequently, a deviation is caused in flow control of the MFC, and the flow of the reaction gas introduced into the reaction chamber is affected.

In a related technology, an equipment engineer usually shut down the gas delivery device regularly to test replacement parts such as a valve, the gas inlet pipeline, and a voltage regulator, and huge costs are caused. In addition, a user is prompted to install the MFC correctly only by setting prompt information. If an installation error occurs, and information about the installation error cannot be prompted in time, the installation error is usually discovered only in the subsequent fabrication process and even discovered after low-yield or low-reliability finished products or even scrapped finished products are produced, and a huge loss is caused.

It should be noted that information disclosed in the above background section is used merely for a better understanding of the background of the present disclosure. Therefore, the background may include information that does not constitute the prior art known to persons of ordinary skill in the art.

### SUMMARY

According to a first aspect of the embodiments of the present disclosure, a detection method for a gas delivery device is provided. The detection method includes: controlling a gas inlet of a machine flow control apparatus to be connected to a first gas inlet pipeline, and controlling a gas inlet valve of the gas inlet to be opened and a gas delivery valve of the machine flow control apparatus to be closed; controlling a pump valve of the machine flow control apparatus to be opened, and controlling the pump valve to be closed after a flow rate of first gas passing through an MFC in the machine flow control apparatus reaches a preset target value; obtaining a first minimum flow rate value of the first gas passing through the MFC within a first preset duration; and determining a valve leakage detection result of the machine flow control apparatus, a gas inlet pipeline blockage detection result, and a detection result of an installation direction of the MFC based on the first minimum flow rate value.

According to a second aspect of the embodiments of the present disclosure, a detection apparatus for a gas delivery device is provided. The detection apparatus includes: a gas source setting module, configured to: control a gas inlet of a machine flow control apparatus to be connected to a first gas inlet pipeline, and control a gas inlet valve of the gas inlet to be opened and a gas delivery valve of the machine flow control apparatus to be closed; a gas pumping control module, configured to: control a pump valve of the machine flow control apparatus to be opened, and control the pump valve to be closed after a flow rate of first gas passing through an MFC in the machine flow control apparatus reaches a preset target value; a detection module, configured to obtain a first minimum flow rate value of the first gas passing through the MFC within a first preset duration; and a determining module, configured to determine a valve leakage detection result of the machine flow control apparatus, a gas inlet pipeline blockage detection result, and a detection result of an installation direction of the MFC based on the first minimum flow rate value.

According to a third aspect of the present disclosure, a gas delivery device is provided. The gas delivery device includes: multiple gas inlet pipelines; a machine flow control apparatus, including a gas inlet, a gas pumping port, a gas delivery port, and an MFC, where the gas inlet is connected to one of the multiple gas inlet pipelines and is provided with a gas inlet valve, the gas pumping port is connected to a suction pump and is provided with a pump valve, the gas delivery port is connected to a reaction chamber of a machine and is provided with a gas delivery valve, and the MFC is located between the gas inlet and the gas delivery port; multiple valve control mechanisms, configured to control opening and closing of the gas inlet valve, the pump valve, and the gas delivery valve; a memory; and a processor connected to the memory and the multiple valve control mechanisms, where the processor is configured to execute the method according to any one of the foregoing implementations based on instructions stored in the memory.

According to a fourth aspect of the present disclosure, a computer-readable storage medium is provided. The computer-readable storage medium stores a program. When the program is executed by a processor, the detection method according to any one of the following implementations is implemented.

It should be understood that the above general description and the following detailed description are only exemplary and explanatory, and should not be construed as a limitation to the present disclosure.

### BRIEF DESCRIPTION OF THE DRAWINGS

The accompanying drawings, which are incorporated in and constitute a part of this description, illustrate the examples of the present disclosure and together with the description, serve to explain the principles of the present disclosure. Apparently, the accompanying drawings in the following description show merely some examples of the present disclosure, and other drawings may be derived from these accompanying drawings by persons of ordinary skill in the art without creative efforts.

FIG. 1 is a schematic diagram of a gas delivery device according to an embodiment of the present disclosure;

FIG. 2 is a flowchart of a detection method according to an embodiment of the present disclosure;

FIG. 3 is a schematic diagram of a change in a detection value of an MFC 24 after a pump valve 221 is closed according to an embodiment of the present disclosure;

FIG. 4 is a sub-flow chart of step S4 according to an embodiment of the present disclosure;

FIG. 5 is a block diagram of a detection apparatus according to an embodiment of the present disclosure; and

FIG. 6 is a block diagram of an electronic device according to an embodiment of the present disclosure.

### DETAILED DESCRIPTION

Exemplary implementations will be described below in further detail with reference to the accompanying drawings. However, the exemplary implementations can be implemented in various forms, and should not be construed as being limited to those described herein. On the contrary, these exemplary implementations are provided to make the present disclosure comprehensive and complete and to fully convey the concept manifested therein to persons skilled in the art. The described features, structures, or characteristics may be incorporated into one or more implementations in any suitable manner In the following description, many specific details are provided to give a full understanding of the implementations of the present disclosure. However, persons skilled in the art will be aware that the technical solutions of the present disclosure may be practiced with one or more of the specific details omitted, or other methods, components, apparatuses, steps, and the like may be used. In other cases, the publicly known technical solutions are not illustrated or described in detail, so as to avoid overshadowing and obscuring various aspects of the present disclosure.

In addition, the accompanying drawings are merely schematic diagrams of the present disclosure, and identical reference numerals in the accompanying drawings denote identical or similar parts. Therefore, repeated description thereof will be omitted. Some of the block diagrams shown in the accompanying drawings are functional entities, and do not necessarily correspond to physically or logically independent entities. These functional entities may be implemented in the form of software, or implemented in one or more hardware modules or integrated circuits, or implemented in different networks and/or processor apparatuses and/or microcontroller apparatuses.

Exemplary implementations of the present disclosure will be described in detail below with reference to the accompanying drawings.

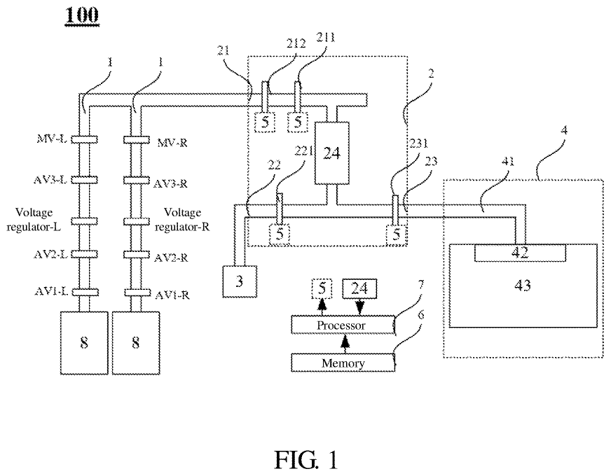

FIG. 1 is a schematic diagram of a gas delivery device according to an embodiment of the present disclosure.

Referring to FIG. 1, the gas delivery device 100 may include:

multiple gas inlet pipelines 1;

a machine flow control apparatus 2, including a gas inlet 21, a gas pumping port 22, a gas delivery port 23, and a mass flow controller (MFC) 24, where the gas inlet 21 is connected to one of the multiple gas inlet pipelines 1 and is provided with a gas inlet valve 211; the gas pumping port 22 is connected to a suction pump 3 and is provided with a pump valve 221; the gas delivery port 23 is connected to a reaction chamber 4 of a machine through a gas delivery pipeline 41 and is provided with a gas delivery valve 231; and the MFC 24 is located between the gas inlet 21 and the gas delivery port 23;

multiple valve control mechanisms 5, configured to control opening and closing of the gas inlet valve 211, the pump valve 221, and the gas delivery valve 231;

a memory 6; and

a processor 7 connected to the memory 6 and the multiple valve control mechanisms 5, where the processor 7 is configured to conduct, based on instructions stored in the memory 6, a detection method provided in the embodiments of the present disclosure.

As shown in FIG. 1, a first end of each gas inlet pipeline 1 is connected to the gas inlet 21 of the machine flow control apparatus 2, and each second end of the gas inlet pipeline 1 is connected to a gas cylinder 8. Gas in the gas cylinder 8 varies with process application scenarios. For example, the gas may include SiH₄, WF₆, or B₂H₆. This is not specially limited in the present disclosure. The gas cylinder 8 is installed in a gas cabinet, and the gas cabinet is provided with installation positions for the multiple gas inlet pipeline 1. Generally, to improve the device reliability, one machine flow control apparatus 2 is usually connected to two or more gas inlet pipelines 1 (gas cylinders 8) for redundancy setting. The gas inlet pipeline 1 is usually provided with multiple valves. In the embodiment shown in FIG. 1, the gas delivery device 100 is provided with two gas inlet pipelines 1. A gas inlet pipeline 1 on the left is provided with valves such as AV1-L, AV2-L, a voltage regulator-L, AV3-L, and MV-L, and a gas inlet pipeline 1 on the right is provided with valves such as AV1-R, AV2-R, a voltage regulator-R, AV3-R, and MV-R. The processor 7 may be connected to the valve control mechanisms (not shown) of the valves on these gas inlet pipelines to control opening and closing of these valves, to determine a specific gas inlet pipeline to be communicated with the gas inlet 21.

In addition to the gas inlet valve 211, a manually-operated flow regulation valve 212 may be disposed at the gas inlet 21 to control a flow rate of incoming gas. In some embodiments, to simplify control logic, one gas inlet valve 211 may alternatively be configured for each gas inlet pipeline 1.

The MFC 24 may be connected to the processor 7 through wired communication or wireless communication, such that the processor 7 obtains flow data of the MFC 24. The gas delivery port 23 is connected to the reaction chamber 4 of the machine through the gas delivery pipeline 41. After entering the gas delivery pipeline 41, the gas enters a reaction environment 43 through a distribution plate 42 (showerhead).

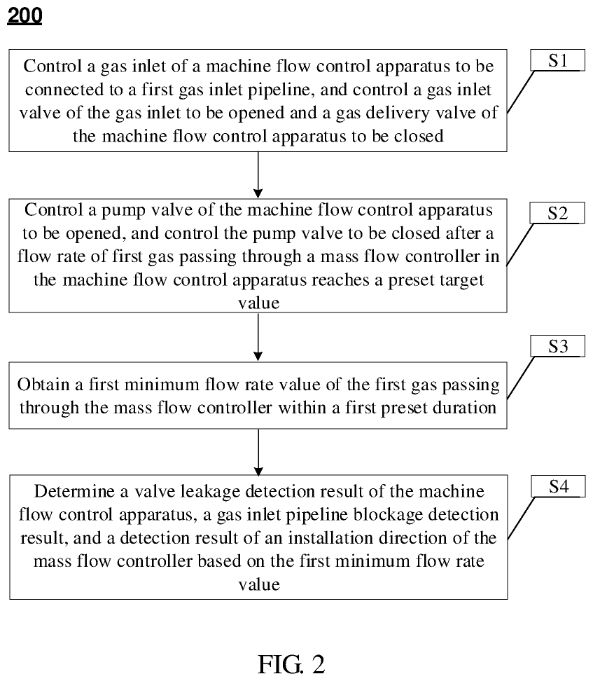

FIG. 2 is a flowchart of a detection method according to an embodiment of the present disclosure. The detection method shown in FIG. 2 may be used to detect the gas delivery device 100 shown in FIG. 1.

Referring to FIG. 2, the detection method 200 may include the following steps.

Step S1. Control a gas inlet of a machine flow control apparatus to be connected to a first gas inlet pipeline, and control a gas inlet valve of the gas inlet to be opened and a gas delivery valve of the machine flow control apparatus to be closed.

Step S2. Control a pump valve of the machine flow control apparatus to be opened, and control the pump valve to be closed after a flow rate of first gas passing through an MFC in the machine flow control apparatus reaches a preset target value.

Step S3. Obtain a first minimum flow rate value of the first gas passing through the MFC within first preset duration.

Step S4. Determine a valve leakage detection result of the machine flow control apparatus, a gas inlet pipeline blockage detection result, and a detection result of an installation direction of the MFC based on the first minimum flow rate value.

According to this embodiment of the present disclosure, various valves of the machine flow control apparatus are controlled in a normal working state. In this way, pipeline blockage, valve leakage, and an incorrect installation manner of the gas delivery device can be detected at one time during a processing gap of the machine without shutting down the machine. Therefore, a short detection time is required, many items can be detected, and high detection efficiency and low detection costs are achieved, thereby increasing detection frequency at any time, improving the problem discovery accuracy and timeliness, and effectively improving the reliability of the gas delivery device and a process yield.

The following describes the steps of the detection method 200 in details.

In step S1, the gas inlet of the machine flow control apparatus is controlled to be connected to the first gas inlet pipeline, and the gas inlet valve of the gas inlet is controlled to be opened and the gas delivery valve of the machine flow control apparatus is controlled to be closed.

In this embodiment of the present disclosure, the processor 7 first controls opening and closing of valves of various gas inlet pipelines to connect one gas inlet pipeline 1 to the gas inlet 21 and close valves of other gas inlet pipelines. Herein, the gas inlet pipeline 1 selected by default is referred to as a first gas inlet pipeline. Then, the processor 7 controls the gas inlet valve 211 to be opened, and controls both the pump valve 221 and the gas delivery valve 231 to be closed to start detection.

In step S2, the pump valve of the machine flow control apparatus is controlled to be opened, and the pump valve is controlled to be closed after the flow rate of the first gas passing through the MFC in the machine flow control apparatus reaches the preset target value.

In this embodiment of the present disclosure, the pump valve 221 is opened after the gas inlet valve 211 keeps opened for a period of time, to control the flow rate of the gas passing through the MFC 24 to reach the preset target value. The preset target value means that: The flow rate of the gas passing through the MFC 24 is a flow rate in a normal working state (the gas is supplied under normal pressure) to be in preparation for subsequent measurement. In an embodiment, the preset target value may be set according to a type of gas (that is, a type of the first gas) delivered in the first gas inlet pipeline and a type of a process to be conducted in the reaction chamber 4 of the machine. For example, the preset target value is 50-500 sccm. In an embodiment, when the type of the gas is tungsten hexafluoride (WF₆), the preset target value may be, for example, 250 sccm. In another embodiment, persons skilled in the art may set the preset target value based on an actual working condition. No limitation is set thereto in the present disclosure.

In an embodiment, the pump valve 221 may be set to be opened after the gas inlet valve 211 keeps opened for second preset duration. The second preset duration may be, for example, not greater than 10 s, for example, 1 s, 2 s, 3 s, or 5 s. The second preset duration is not specially limited in the present disclosure, provided that the gas in the MFC 24 can form a path within the second preset duration.

To ensure that the flow rate of the gas passing through the MFC 24 is controlled to stably reach the preset target value, the pump valve 221 may alternatively be closed in a period of time (for example, 10 s or 20 s) after the flow rate of the gas passing through the MFC 24 is controlled to reach the preset target value, instead of closing the pump valve 221 immediately after the flow rate reaches the preset target value. To facilitate control implementation, alternatively, duration (third preset duration) for which the pump valve 221 keeps opened in a working condition and after which the flow rate of the gas passing through the machine flow control apparatus 2 can stably reach the preset target value may be calculated in advance, and then in a subsequent test, the pump valve 221 is directly controlled to keep opened for the third preset duration in the working condition. In some embodiments, the third preset duration may be, for example, 30 s, 40 s, 50 s, or 60 s.

In step S3, the first minimum flow rate value of the first gas passing through the MFC within the first preset duration is obtained.

After the pump valve 221 is closed, because the gas inlet valve 211 is opened, the gas is continuously supplied to the machine flow control apparatus 2 in the first gas inlet pipeline. The introduced gas not only enters the machine flow control apparatus 2, but also enters various gas ventilation pipelines (including a gas delivery pipeline, a gas inlet pipeline, and a gas pumping pipeline) connected to the machine flow control apparatus 2, and is cut off when flowing to a closed valve.

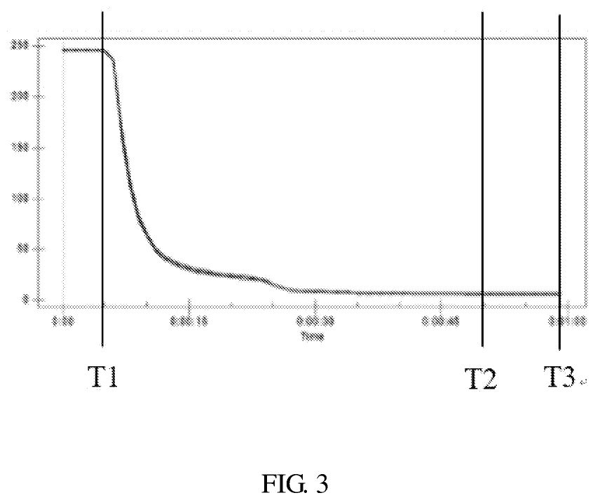

FIG. 3 is a schematic diagram of a change in a detection value of an MFC 24 after a pump valve 221 is closed according to an embodiment of the present disclosure.

Referring to FIG. 3, generally, if a flow rate of incoming gas is normal, the valve does not leak, and the MFC 24 operates normally. When both the pump valve 221 and a gas delivery valve 231 are closed, starting from a time point T1 at which the pump valve 221 is closed, gas is supplied to the machine flow control apparatus 2 in a first gas inlet pipeline for a period of time, the gas in the machine flow control apparatus 2 should be saturated, and even if the gas continues to be supplied, no larger flow rate can be obtained (for example, a time point T2 to a time point T3 in FIG. 3).

In an ideal case, the flow rate of the gas approaches and is ultimately 0. However, due to impact of factors such as parts or interaction in a pipeline, even if the gas is saturated, the MFC 24 still displays a quite small flow rate of the gas. A normal reading is approximately 0.1 sccm (for example, a reading corresponding to the time point T3 in FIG. 3). Therefore, readings of the MFC 24 in a period of time may be observed after the pump valve 221 is closed, a minimum flow rate value is extracted, and whether the gas in the machine flow control apparatus 2 has been saturated or whether the MFC 24 conducts display abnormally is determined by determining whether the minimum flow rate value satisfies a requirement of the normal reading.

In this embodiment of the present disclosure, a first minimum flow rate value between the time point T1 to the time point T3 in FIG. 3 may be detected. Duration between the time point T1 and the time point T3 may be, for example, first preset duration. The first preset duration may be set to, for example, 50-100 s, and may preferably be set to 60 s, to ensure that the gas in the machine flow control apparatus 2 is saturated. To detect the first minimum flow rate value within the first preset duration, sampling on readings of the MFC 24 may be started after the pump valve 221 is closed (that is, at the time point T1), or sampling on readings of the MFC 24 may be started after a period of time (for example, at the time point T2) when an estimated flow rate is relatively small, to save sampling and calculation resources. According to historical data analysis, the readings of the MFC 24 usually change relatively stably in 30 s after the pump valve 221 is closed.

In step S4, the valve leakage detection result of the machine flow control apparatus, the gas inlet pipeline blockage detection result, and the detection result of the installation direction of the MFC based on the first minimum flow rate value.

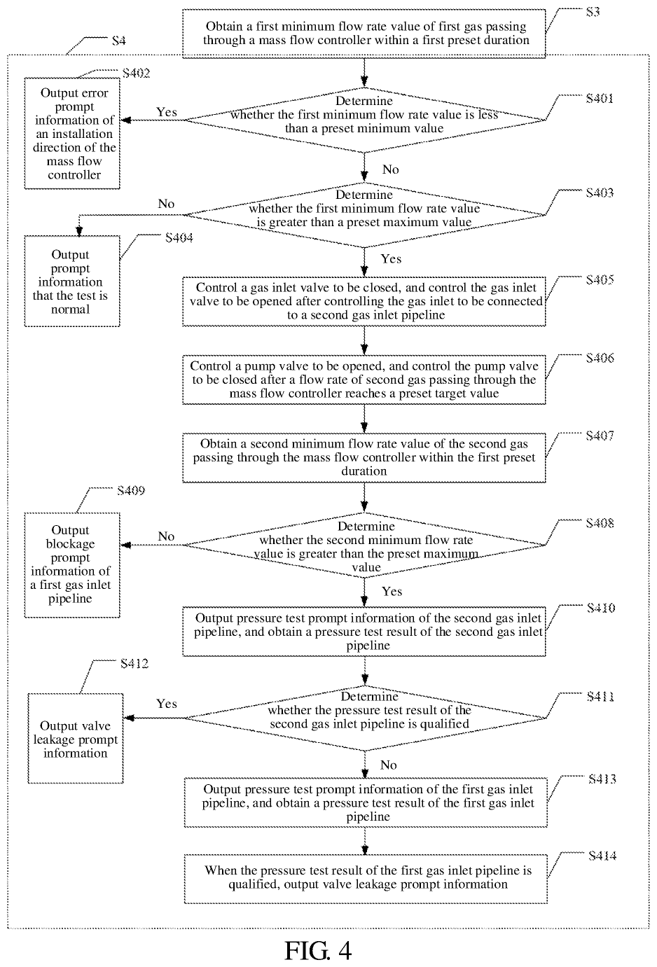

FIG. 4 is a sub-flow chart of step S4 according to an embodiment of the present disclosure.

Referring to FIG. 4, in step S401, whether the first minimum flow rate value is less than a preset minimum value is determined, and if the first minimum flow rate value is less than the preset minimum value, step S402 of outputting error prompt information of the installation direction of the MFC is conducted.

In a normal case, when gas is saturated, the MFC 24 displays a relatively small flow rate. If a reading of the MFC is less than a normal reading (the preset minimum value), or even is 0, it indicates that a zero point of the MFC has drifted. The inventor found that, since the zero point of the MFC is set according to an absolute flow direction of the gas (the gas flows from top to bottom or horizontally flows), when the absolute flow direction of the gas in the MFC changes because the installation direction of the MFC changes, the zero point of the MFC set according to the installation direction also changes. Therefore, in this embodiment of the present disclosure, the minimum flow rate value is detected to determine whether the zero point of the MFC is drifted, so as to determine whether the installation direction of the MFC is correct. This avoids careless omission easily caused when installation personnel conduct MFC installation or calibration in a related technology, and effectively avoids a cost loss caused due to an installation error.

In an embodiment, the preset minimum value may be set to, for example, 0.1 sccm. After both the pump valve and the gas delivery valve keep closed for a quite long time, in a normal case, the reading of the MFC is not less than the preset minimum value. Therefore, when the reading of the MFC is less than the preset minimum value, it indicates that the zero point of the MFC has shifted, it can be determined that the installation direction of the MFC is incorrect.

If the first minimum flow rate value is greater than the preset minimum value, step S403 of determining whether the first minimum flow rate value is greater than a preset maximum value is conducted. If the first minimum flow rate value is not greater than the preset maximum value, step S404 of outputting prompt information that the test is normal. In an embodiment, the preset maximum value may be set to, for example, 5 sccm.

As described above, after the pump valve 221 keeps closed for a period of time, the gas in the machine flow control apparatus 2 should be saturated. In this case, if a flow rate of the gas is still relatively large, there may be two cases. In one case, because a valve (the pump valve 221 or the gas delivery valve 231) leaks, the gas in the machine flow control apparatus 2 never becomes saturated. In the other case, because a gas inlet pipeline is blocked, a gas supply speed is low, and gas space in the machine flow control apparatus 2 is still not fully filled during detection conducted after the first preset duration. Therefore, when it is determined in step S403 that the first minimum flow rate value is greater than the preset maximum value, step S405 may be conducted to conduct further detection to distinguish which one of the foregoing two cases occurs.

In step S405, the gas inlet valve 211 is controlled to be closed, and the gas inlet valve 211 is controlled to be opened after the gas inlet 21 is controlled to be connected to a second gas inlet pipeline. The second gas inlet pipeline is used to deliver second gas, a type of the second gas may be the same as that of the first gas or different from that of the first gas.

In step S406, the pump valve 221 is controlled to be opened, and the pump valve 221 is controlled to be closed after a flow rate of the second gas passing through the MFC 24 reaches the preset target value.

In step S407, a second minimum flow rate value of the second gas passing through the MFC 24 within the first preset duration is obtained.

In step S408, whether the second minimum flow rate value is greater than the preset maximum value is determined, and if the second minimum flow rate value is not greater than the preset maximum value, step S409 of outputting blockage prompt information of the first gas inlet pipeline is conducted.

If the first gas inlet pipeline is replaced with the second gas inlet pipeline to conduct a test again, the minimum flow rate value returns to normal (not greater than the preset maximum value), it indicates that a previous abnormal value is caused by the first gas inlet pipeline. In this case, it may be determined that a speed of the previous gas supply is relatively low because the previously connected first gas inlet pipeline is blocked. In this case, the blockage prompt information of the first gas inlet pipeline is output to remind maintenance personnel to check the first gas inlet pipeline.

If the first gas inlet pipeline is replaced with the second gas inlet pipeline to conduct a test again, the minimum flow rate value is still greater than the preset maximum value, whether the two gas inlet pipelines are blocked or valve leakage occurs, or whether the two gas inlet pipelines are blocked and valve leakage occurs cannot be determined. In this case, further detection may be conducted. For example, pressure test prompt information of the second gas inlet pipeline is output, and a pressure test result of the second gas inlet pipeline is obtained after a pressure test on the second gas inlet pipeline is completed, to determine the valve leakage detection result and a blockage detection result of the second gas inlet pipeline.

FIG. 4 shows an embodiment of further detection. Persons skilled in the art may alternatively set other determining logic to process a case in which the second minimum flow rate value is still greater than the preset maximum value.

In step S410, pressure test prompt information of the second gas inlet pipeline is output, and a pressure test result of the second gas inlet pipeline is obtained.

In step S411, whether the pressure test result of the second gas inlet pipeline is qualified is determined; if the pressure test result of the second gas inlet pipeline is qualified, step S412 of outputting valve leakage prompt information is conducted; and if the pressure test result of the second gas inlet pipeline is unqualified, step S413 is conducted.

In step S413, pressure test prompt information of the first gas inlet pipeline is output, and a pressure test result of the first gas inlet pipeline is obtained after a pressure test on the first gas inlet pipeline is completed.

In step S414, when the pressure test result of the first gas inlet pipeline is qualified, valve leakage prompt information is output.

If the pressure test result of the first gas inlet pipeline is also unqualified, whether valve leakage occurs still cannot be determined. In this case, detection may be conducted after a related operator replaces parts of the gas inlet pipelines. In some embodiments, a pressure test on a gas inlet pipeline may be controlled by the processor 7 and the pressure test is automatically conducted to automatically obtain a pressure test result. In some other embodiments, a pressure test on a gas inlet pipeline may be manually conducted by related personnel after the related personnel receives pressure test prompt information of the gas inlet pipeline, and after a pressure test result is obtained, the pressure test result is input into a human-computer interaction module (not shown) connected to the processor 7. The pressure test method for the gas inlet pipeline may be a general method. Details are not described in the present disclosure.

When there are more than two gas inlet pipelines 1, if the second minimum flow rate value is still greater than the preset maximum value, another gas inlet pipeline may also be replaced to continue to conduct measurement, pressure test prompt information of a gas inlet pipeline is output only when minimum flow rate values corresponding to all available gas inlet pipelines are greater than the preset maximum value, and then a pressure test is conducted on the gas inlet pipeline. This avoids as much as possible test time extension and test efficiency reduction caused by the pressure test on the gas inlet pipeline.

Multiple gas inlet pipelines 1 may be connected to a same type of gas cylinder or multiple types of gas cylinders. Generally, each type of gas is corresponding to at least two gas inlet pipelines to satisfy redundancy setting. When the gas inlet 21 is connected to multiple gas inlet pipelines, all the gas inlet pipelines may be successively used to conduct the test including step S1 to step S4, to directly and efficiently detect whether each gas inlet pipeline is blocked without conducting a pressure test. For example, a valve leakage status and the installation direction of the MFC are first tested through the test including steps S1 to S4; and when it is determined that no valve leakage occurs and the installation direction of the MFC is normal, another gas inlet pipeline is connected, and whether the another gas inlet pipeline is blocked is directly determined through measurement, thereby simplifying determining logic.

The foregoing valve leakage prompt information, gas inlet pipeline blockage prompt information, and error prompt information of the installation direction of the MFC may all be displayed through a display apparatus connected to the processor 7, or indicated through a sound, light, and electrical prompting apparatus installed on the gas delivery device. This is not specially set in the present disclosure.

In conclusion, according to the detection method in the embodiments of the present disclosure, an original mechanical apparatus may be started at a pre-deposition (pre-coat) stage before the machine enters a working state, to complete a test on the gas delivery device connected to the machine, and multiple detection results are output when detection is conducted for one time. In addition, the detection method is convenient to implement, and low detection costs and high detection efficiency are achieved.

Corresponding to the foregoing method embodiment, the present disclosure further provides a detection apparatus. The detection apparatus can be configured to execute the foregoing method embodiment.

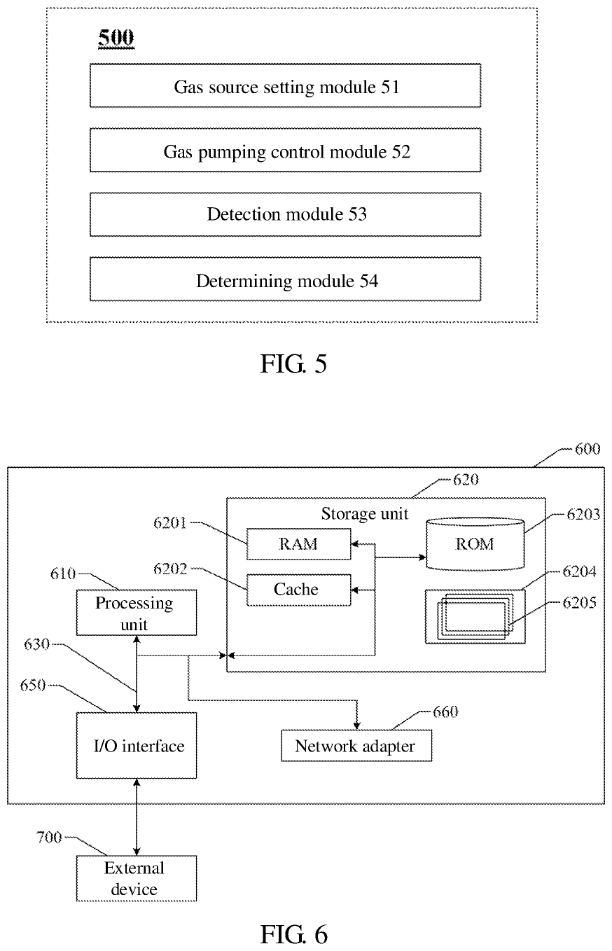

FIG. 5 is a block diagram of a detection apparatus according to an exemplary embodiment of the present disclosure.

Referring to FIG. 5, the detection apparatus 500 may include:

a gas source setting module 51, configured to: control a gas inlet of a machine flow control apparatus to be connected to a first gas inlet pipeline, and control a gas inlet valve of the gas inlet to be opened and a gas delivery valve of the machine flow control apparatus to be closed;

a gas pumping control module 52, configured to: control a pump valve of the machine flow control apparatus to be opened, and control the pump valve to be closed after a flow rate of first gas passing through an MFC in the machine flow control apparatus reaches a preset target value;

a detection module 53, configured to obtain a first minimum flow rate value of the first gas passing through the MFC within first preset duration; and

a determining module 54, configured to determine a valve leakage detection result of the machine flow control apparatus, a gas inlet pipeline blockage detection result, and a detection result of an installation direction of the MFC based on the first minimum flow rate value.

In an exemplary embodiment of the present disclosure, the determining module 54 is configured to: when the first minimum flow rate value is less than a preset minimum value, output error prompt information of the installation direction of the MFC.

In an exemplary embodiment of the present disclosure, the determining module 54 is configured to: when the first minimum flow rate value is greater than a preset maximum value, control the gas inlet valve to be closed, and control the gas inlet valve to be opened after controlling the gas inlet to be connected to a second gas inlet pipeline; control the pump valve to be opened, and control the pump valve to be closed after a flow rate of second gas passing through the MFC reaches the preset target value; obtain a second minimum flow rate value of the second gas passing through the MFC within the first preset duration; if the second minimum flow rate value is greater than the preset maximum value, output pressure test prompt information of the second gas inlet pipeline, and obtain a pressure test result of the second gas inlet pipeline to determine the valve leakage detection result and the gas inlet pipeline blockage detection result; and if the second minimum flow rate value is less than or equal to the preset maximum value, output blockage prompt information of the first gas inlet pipeline.

In an exemplary embodiment of the present disclosure, the determining module 54 is configured to: when the pressure test result of the second gas inlet pipeline is qualified, output valve leakage prompt information; when the pressure test result of the second gas inlet pipeline is unqualified, output pressure test prompt information of the first gas inlet pipeline, and obtain a pressure test result of the first gas inlet pipeline; and when the pressure test result of the first gas inlet pipeline is qualified, output the valve leakage prompt information.

In an exemplary embodiment of the present disclosure, the first preset duration is 50-100 s.

In an exemplary embodiment of the present disclosure, the gas pumping control module 52 is configured to control the pump valve to be opened after the gas inlet valve keeps opened for second preset duration.

In an exemplary embodiment of the present disclosure, the second preset duration is not greater than 10 s.

In an exemplary embodiment of the present disclosure, the gas pumping control module 52 is configured to close the pump valve after it is determined that the pump valve keeps opened for third preset duration.

In an exemplary embodiment of the present disclosure, the third preset duration is 30 s.

In an exemplary embodiment of the present disclosure, the preset minimum value is 0.1 sccm.

In an exemplary embodiment of the present disclosure, the preset maximum value is 5 sccm.

In an exemplary embodiment of the present disclosure, types of the first gas include SiH₄, WF₆, or B₂H₆.

In an exemplary embodiment of the present disclosure, the preset target value is 50-500 sccm.

Because various functions of the apparatus 500 have been described in details in the method embodiment corresponding to the apparatus 500, details are not described again in the present disclosure.

It should be noted that although several modules or units of a device for action execution are mentioned in the above detailed description, such division is not mandatory. Actually, according to the implementations of the present disclosure, features and functions of two or more modules or units described above can be embodied in one module or unit. On the contrary, features and functions of a module or unit described above can be further divided into multiple modules or units to be embodied.

In an exemplary embodiment of the present disclosure, an electronic device that can implement the foregoing method may further be provided.

Persons skilled in the art can understand that each aspect of the present disclosure can be implemented as a system, a method, or a program product. Therefore, each aspect of the present disclosure may be specifically implemented in the following forms, namely: a complete hardware implementation, a complete software implementation (including firmware, microcode, or the like), or a combination of hardware and software implementations. These implementations may be collectively referred to as “circuits”, “modules”, or “systems” herein.

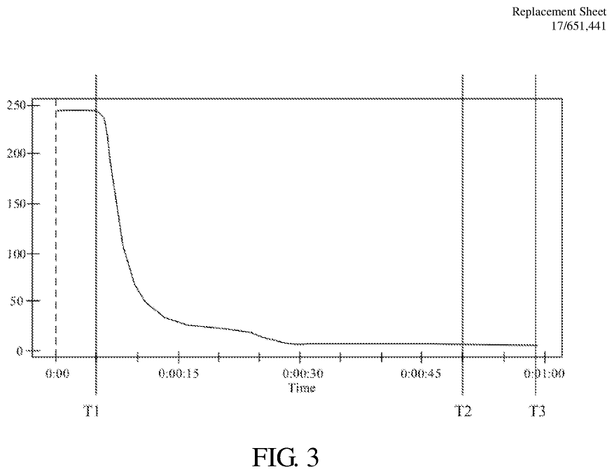

An electronic device 600 according to this implementation of the present disclosure is described below with reference to FIG. 6. The electronic device 600 shown in FIG. 6 is only used as an example, and should not constitute any limitation to a function and an application range of the embodiments of the present disclosure.

As shown in FIG. 6, the electronic device 600 is represented in a form of a general-purpose computing device. Components of the electronic device 600 may include, but are not limited to, at least processing unit 610, at least one storage unit 620, and a bus 630 connected to different system components (including the storage unit 620 and the processing unit 610).

The storage unit stores program code, and the program code can be executed by the processing unit 610, such that the processing unit 610 conducts the steps that are conducted in various exemplary implementations of the present disclosure and that are described in the foregoing “exemplary method” section in this specification. For example, the processing unit 610 may conduct the steps shown in FIG. 2.

The storage unit 620 may include a readable medium in a form of a volatile storage unit, such as a random access storage unit (RAM) 6201 and/or a cache storage unit 6202, and may further include a read-only storage unit (ROM) 6203.

The storage unit 620 may further include a program/utility tool 6204 including a set (at least one) of program modules 6205. Such program module 6205 includes, but is not limited to, an operating system, one or more application programs, another program module, and program data, and each of these examples or a combination of these examples may include an implementation of a network environment.

The bus 630 may represent one or more of several types of bus structures, including a storage unit bus, a storage unit controller, a peripheral bus, a graphics acceleration port, a processing unit, or a local bus using any one of multiple bus structures.

The electronic device 600 may also communicate with one or more external devices 700 (such as a keyboard, a pointing device, and a Bluetooth device), and may also communicate with one or more devices that enable a user to interact with the electronic device 600, and/or communicate with any device (such as a router and a modem) that enables the electronic device 600 to communicate with one or more other computing devices. Such communication may be conducted through an input/output (I/O) interface 650. In addition, the electronic device 600 may also communicate with one or more networks (such as a local area network (LAN), a wide area network (WAN), and/or a public network such as the Internet) through a network adapter 660. As shown in the figure, the network adapter 660 communicates with another module of the electronic device 600 through the bus 630. It should be understood that although not shown in the figure, other hardware and/or software modules, including but not limited to: microcode, a device driver, a redundancy processing unit, an external disk drive array, a RAID system, a tape drive, a data backup storage system, and the like, may be used in combination with the electronic device 600.

Through the description of the above implementations, persons skilled in the art can easily understand that the example embodiments described herein can be implemented by software, or can be implemented by combining software with necessary hardware. Therefore, the technical solution according to the implementations of the present disclosure can be embodied in a form of a software product. The software product may be stored in a non-volatile storage medium (which may be a CD-ROM, a USB flash drive, a removable hard disk, or the like) or on a network, and include several instructions to enable a computing device (which may be a personal computer, a server, a terminal apparatus, a network device, or the like) to implement the method according to the implementations of the present disclosure.

In an exemplary embodiment of the present disclosure, a computer-readable storage medium is further provided, and the computer-readable storage medium stores program product that can implement the foregoing method of this specification. In some possible implementations, various aspects of the present disclosure may also be implemented in a form of a program product, including program code. When the program product is run on a terminal device, the program code is used to enable the terminal device to execute steps described in various exemplary implementations according to various exemplary embodiments of the present disclosure in the above-mentioned “exemplary method” in this specification.

The program product used to implement the foregoing method according to the embodiments of the present disclosure may use a portable compact disk read-only memory (CD-ROM) and include program code, and may be run on a terminal device, such as a personal computer. However, the program product of the present disclosure is not limited to this. In this document, the readable storage medium may be any tangible medium that includes or stores a program, and the program may be used by or in combination with an instruction execution system, apparatus, or device.

The program product may be any combination of one or more readable media. A readable medium may be a readable signal medium or a readable storage medium. The readable storage medium may be, for example, but is not limited to, an electrical, magnetic, optical, electromagnetic, infrared, or semiconductor system, apparatus, or device, or any combination of the above. More specific embodiments of the computer-readable storage medium may include, but are not limited to: an electric connector with one or more wires, a portable computer magnetic disk, a hard drive, a random access memory (RAM), a read-only memory (ROM), an erasable programmable read-only memory (EPROM or flash drive), an optical fiber, a compact disk read-only memory (CD-ROM), an optical storage device, a magnetic storage device, or any proper combination of the above.

The computer-readable signal medium may include a data signal propagated in a baseband or propagated as a part of a carrier, and carries computer-readable program code. Such a propagated data signal may be in multiple forms, including, but not limited to an electromagnetic signal, an optical signal, or any proper combination of the above. The computer-readable signal medium may alternatively be any computer-readable storage medium except the computer-readable medium. The computer-readable storage medium may send, propagate or transmit a program used by or used in combination with an instruction execution system, apparatus or device.

The program code included in the computer-readable medium may be transmitted by using any suitable medium, including, but is not limited to radio, an electric wire, an optical fiber, RF, and the like, or any proper combination of the above.

Program code for executing the operations in the present disclosure may be compiled by using one or more program design languages or a combination thereof. The programming languages include object oriented programming languages, such as Java and C++, and further include conventional procedural programming languages, such as the “C” language or a similar programming language. The program code can be executed fully on a user computing device, executed partially on a user computing device, executed as an independent software package, executed partially on a user computer and partially on a remote computer, or executed fully on a remote computing device or a server. In a case in which a remote computing device is involved, the remote computing device may be connected to a user computing device via any type of network, including a local area network (LAN) or a wide area network (WAN), or may be connected to an external computing device (for example, connected via the Internet by using an Internet service provider).

In addition, the foregoing accompanying drawings are merely schematic illustrations of processing steps included in the method according to the exemplary embodiments of the present disclosure, and are not intended for limitation. It is easily understood that the processing steps shown in the foregoing accompanying drawings do not indicate or limit a chronological sequence of the processing steps. In addition, it is also easily understood that the processing steps can be conducted synchronously or asynchronously, for example, in multiple modules.

Persons skilled in the art can easily figure out other implementation solutions of the present disclosure after considering this specification and practicing the present disclosure. This application is intended to cover any variations, purposes, or adaptive changes of the present disclosure. Such variations, purposes, or adaptive changes follow the general principle of the present disclosure and include common knowledge or conventional technical means in the technical field that is not disclosed in the present disclosure. This specification and embodiments are merely considered as illustrative, and the real scope and spirit of the present disclosure are pointed out by the appended claims.

### INDUSTRIAL APPLICABILITY

According to the embodiments of the present disclosure, various valves of the machine flow control apparatus are controlled in a normal working state. In this way, pipeline blockage, valve leakage, and an incorrect installation manner of the gas delivery device can be detected at one time during a processing gap of the machine without shutting down the machine. Therefore, a short detection time is required, many items can be detected, and high detection efficiency and low detection costs are achieved, thereby increasing detection frequency at any time, improving the problem discovery accuracy and timeliness, and effectively improving the reliability of the gas delivery device and a process yield.

1. A detection method for a gas delivery device, comprising:
controlling a gas inlet of a machine flow control apparatus to be connected to a first gas inlet pipeline, and controlling a gas inlet valve of the gas inlet to be opened and a gas delivery valve of the machine flow control apparatus to be closed;
controlling a pump valve of the machine flow control apparatus to be opened, and controlling the pump valve to be closed after a flow rate of first gas passing through a mass flow controller in the machine flow control apparatus reaches a preset target value;
obtaining a first minimum flow rate value of the first gas passing through the mass flow controller within a first preset duration; and
determining a valve leakage detection result of the machine flow control apparatus, a gas inlet pipeline blockage detection result, and a detection result of an installation direction of the mass flow controller based on the first minimum flow rate value.

2. The detection method according to claim 1, wherein the determining a valve leakage detection result of the machine flow control apparatus, a gas inlet pipeline blockage detection result, and a detection result of an installation direction of the mass flow controller based on the first minimum flow rate value comprises:
when the first minimum flow rate value is less than a preset minimum value, outputting error prompt information of the installation direction of the mass flow controller.

3. The detection method according to claim 1, wherein the determining a valve leakage detection result of the machine flow control apparatus, a gas inlet pipeline blockage detection result, and a detection result of an installation direction of the mass flow controller based on the first minimum flow rate value comprises:
when the first minimum flow rate value is greater than a preset maximum value, controlling the gas inlet valve to be closed, and controlling the gas inlet valve to be opened after controlling the gas inlet to be connected to a second gas inlet pipeline;
controlling the pump valve to be opened, and controlling the pump valve to be closed after a flow rate of second gas passing through the mass flow controller reaches the preset target value;
obtaining a second minimum flow rate value of the second gas passing through the mass flow controller within the first preset duration;
if the second minimum flow rate value is greater than the preset maximum value, outputting pressure test prompt information of the second gas inlet pipeline, and obtaining a pressure test result of the second gas inlet pipeline to determine the valve leakage detection result and the gas inlet pipeline blockage detection result; and
if the second minimum flow rate value is less than or equal to the preset maximum value, outputting blockage prompt information of the first gas inlet pipeline.

4. The detection method according to claim 3, wherein the obtaining a pressure test result of the second gas inlet pipeline to determine the valve leakage detection result and the gas inlet pipeline blockage detection result comprises:
when the pressure test result of the second gas inlet pipeline is qualified, outputting valve leakage prompt information;
when the pressure test result of the second gas inlet pipeline is unqualified, outputting pressure test prompt information of the first gas inlet pipeline, and obtaining a pressure test result of the first gas inlet pipeline; and
when the pressure test result of the first gas inlet pipeline is qualified, outputting the valve leakage prompt information.

5. The detection method according to claim 1, wherein the first preset duration is 50-100 s.

6. The detection method according to claim 1, wherein the controlling a pump valve of the machine flow control apparatus to be opened comprises:
controlling the pump valve to be opened after the gas inlet valve keeps opened for a second preset duration.

7. The detection method according to claim 6, wherein the second preset duration is not greater than 10 s.

8. The detection method according to claim 1, wherein the controlling the pump valve to be closed after a flow rate of first gas passing through a mass flow controller in the machine flow control apparatus reaches a preset target value comprises:
closing the pump valve after it is determined that the pump valve keeps opened for a third preset duration.

9. The detection method according to claim 8, wherein the third preset duration is 30 s.

10. The detection method according to claim 2, wherein the preset minimum value is 0.1 sccm.

11. The detection method according to claim 3, wherein the preset maximum value is 5 sccm.

12. The detection method according to claim 1, wherein types of the first gas comprise SiH₄, WF₆, or B₂H₆.

13. The detection method according to claim 1, wherein the preset target value is 50-500 sccm.

14. A detection apparatus for a gas delivery device, comprising:
a gas source setting module, configured to: control a gas inlet of a machine flow control apparatus to be connected to a first gas inlet pipeline, and control a gas inlet valve of the gas inlet to be opened and a gas delivery valve of the machine flow control apparatus to be closed;
a gas pumping control module, configured to: control a pump valve of the machine flow control apparatus to be opened, and control the pump valve to be closed after a flow rate of first gas passing through a mass flow controller in the machine flow control apparatus reaches a preset target value;
a detection module, configured to obtain a first minimum flow rate value of the first gas passing through the mass flow controller within a first preset duration; and
a determining module, configured to determine a valve leakage detection result of the machine flow control apparatus, a gas inlet pipeline blockage detection result, and a detection result of an installation direction of the mass flow controller based on the first minimum flow rate value.

15. A gas delivery device, comprising:
multiple gas inlet pipelines;
a machine flow control apparatus, comprising a gas inlet, a gas pumping port, a gas delivery port, and a mass flow controller; wherein the gas inlet is connected to one of the multiple gas inlet pipelines and is provided with a gas inlet valve; the gas pumping port is connected to a suction pump and is provided with a pump valve; the gas delivery port is connected to a reaction chamber of a machine and is provided with a gas delivery valve; and the mass flow controller is located between the gas inlet and the gas delivery port;
multiple valve control mechanisms, configured to control opening and closing of the gas inlet valve, the pump valve, and the gas delivery valve;
a memory; and
a processor, connected to the memory and the multiple valve control mechanisms; wherein the processor is configured to execute the detection method according to claim 1, based on instructions stored in the memory.

16. A computer-readable storage medium, wherein the computer-readable storage medium stores a program; and when the program is executed by a processor, the detection method according to claim 1 is implemented.
